(19) United States
(12) Patent Application Publication
(10) Pub. No.: US 2023/0318604 A1
(43) Pub. Date: Oct. 5, 2023

(54) CONTROL CIRCUIT AND DRIVING CIRCUIT

(71) Applicant: SONY SEMICONDUCTOR SOLUTIONS CORPORATION, KANAGAWA (JP)

(72) Inventors: AKIRA ARAI, TOKYO (JP); HISASHI OWA, KANAGAWA (JP); TAKASHI NAKAMURA, KANAGAWA (JP)

(21) Appl. No.: 18/043,079

(22) PCT Filed: Jul. 8, 2021
(86) PCT No.: PCT/JP2021/025759

§ 371 Date: Feb. 27, 2023

(30) Foreign Application Priority Data
Sep. 7, 2020 (JP) 2020-149817

(51) Int. Cl. H03K 19/0185; G05F 1/575

(52) U.S. Cl. CPC H03K 19/018578; G05F 1/575

(57) ABSTRACT

Provided is a control circuit that controls the amplitude by using a voltage regulator and that has improved accuracy in amplitude control.

The control circuit includes a first voltage regulator and a second voltage regulator. The first voltage regulator in the control circuit generates one of a pair of voltages from a predetermined reference voltage and supplies the one of the pair of voltages to one of a power supply terminal and a ground terminal of a driver. In addition, the second voltage regulator generates the other of the pair of voltages from the one of the pair of voltages and supplies the other of the pair of voltages to the other of the power supply terminal and the ground terminal.

### TECHNICAL FIELD

The present technology relates to a control circuit. In particular, the present technology relates to a control circuit and a driving circuit that use a voltage regulator.

### BACKGROUND ART

In the related art, a transmission-side driving circuit of a communication interface often includes, in addition to a driver, a voltage regulator disposed in the driving circuit to control the amplitude of the driver. For example, there has been proposed a driving circuit that is provided with voltage regulators respectively on a power supply side and a ground side along with drivers (refer to PTL 1, for example). The power supply-side voltage regulator in this driving circuit generates a high-level output of the driver from a predetermined reference voltage. The ground-side voltage regulator generates a low-level output of the driver from the reference voltage.

### CITATION LIST

### Patent Literature

### [PTL 1]

JP-T-2016-525302

### SUMMARY

### Technical Problem

In the related art described above, the voltage regulator is disposed both on the power supply side and on the ground side to improve PSRR (Power Supply Rejection Ratio). However, in the driving circuit described above, input offset of an operational amplifier in the voltage regulator may vary the amplitude of an output signal from the driver. This variation may reduce accuracy achieved when the voltage regulator controls the amplitude.

The present technology has been created in view of the above-described circumstances, and an object of the present technology is to provide a control circuit that controls the amplitude with use of a voltage regulator, the control circuit having improved accuracy in amplitude control.

### Solution to Problem

The present technology has been made to solve the above-described problem, and a first aspect provides a control circuit including a first voltage regulator that generates one of a pair of voltages from a predetermined reference voltage and supplies the one of the pair of voltages to one of a power supply terminal and a ground terminal of a driver, and a second voltage regulator that generates the other of the pair of voltages from the one of the pair of voltages and supplies the other of the pair of voltages to the other of the power supply terminal and the ground terminal. This configuration is effective in accurately controlling the amplitude.

In addition, in the first aspect, the first voltage regulator may generate a lower voltage of the pair of voltages, and the second voltage regulator may generate a higher voltage of the pair of voltages. This configuration is effective in generating a high voltage from a low voltage.

In addition, in the first aspect, the first voltage regulator may generate a higher voltage of the pair of voltages, and the second voltage regulator may generate a lower voltage of the pair of voltages. This configuration is effective in generating a low voltage from a high voltage.

In addition, in the first aspect, the control circuit may further include a reference voltage generating circuit that generates and supplies the reference voltage to the first voltage regulator. This configuration is effective in inputting the reference voltage to the first voltage regulator.

In addition, in the first aspect, the reference voltage generating circuit may generate the reference voltage by using a predetermined ground voltage as a reference. This configuration is effective in generating the reference voltage with use of the ground voltage as a reference.

In addition, in the first aspect, the reference voltage generating circuit may generate the reference voltage by using a predetermined power supply voltage as a reference. This configuration is effective in generating the reference voltage with use of the power supply voltage as a reference.

In addition, in the first aspect, the first voltage regulator may include a first operational amplifier that outputs the one of the pair of voltages, a first resistor interposed between one of a pair of input terminals of the first operational amplifier and the one of the power supply terminal and the ground terminal, and a second resistor connected at one end to the one of the pair of input terminals, and the other of the pair of input terminals may receive the reference voltage as input. This configuration is effective in amplifying the reference voltage.

In addition, in the first aspect, a predetermined ground voltage may be applied to the other end of the second resistor. This configuration is effective in forming a feedback circuit.

In addition, in the first aspect, a predetermined power supply voltage may be applied to the other end of the second resistor. This configuration is effective in forming a feedback circuit.

In addition, in the first aspect, the second voltage regulator may include a second operational amplifier that outputs the other of the pair of voltages, a third resistor interposed between one of a pair of input terminals of the second operational amplifier and the other of the power supply terminal and the ground terminal, and a fourth resistor connected at one end to the one of the pair of input terminals, and a voltage corresponding to the one of the pair of voltages may be applied to the other of the pair of input terminals. This configuration is effective in amplifying the one of the pair of voltages.

In addition, in the first aspect, the one of the pair of voltages may be applied to the other end of the fourth resistor. This configuration is effective in forming a feedback circuit.

In addition, in the first aspect, a predetermined power supply voltage may be applied to the other end of the fourth resistor. This configuration is effective in forming a feedback circuit.

In addition, a second aspect of the present technology provides a driving circuit including a driver, a first voltage regulator that generates one of a pair of voltages from a predetermined reference voltage and supplies the one of the pair of voltages to one of a power supply terminal and a ground terminal of the driver, and a second voltage regulator that generates the other of the pair of voltages from the one of the pair of voltages and supplies the other of the pair of voltages to the other of the power supply terminal and the ground terminal. This configuration is effective in outputting a signal having an accurately controlled amplitude.

### BRIEF DESCRIPTION OF DRAWINGS

FIG. 1 is a block diagram depicting a configuration example of an interface circuit according to a first embodiment of the present technology.

FIG. 2 is a block diagram depicting a configuration example of a driving circuit according to the first embodiment of the present technology.

FIG. 3 is a circuit diagram depicting a configuration example of the driving circuit according to the first embodiment of the present technology.

FIG. 4 is a circuit diagram depicting a configuration example of a driving circuit according to a comparative example.

FIG. 5 is a circuit diagram depicting a configuration example of a high-voltage-side voltage regulator with a different feedback circuit according to the first embodiment of the present technology.

FIG. 6 is a circuit diagram depicting a configuration example of a reference voltage generating circuit using a ground voltage as a reference and a low-voltage-side voltage regulator with a different feedback circuit according to the first embodiment of the present technology.

FIG. 7 is a circuit diagram depicting a configuration example of the reference voltage generating circuit using a power supply voltage as a reference and the low-voltage-side voltage regulator with the different feedback circuit according to the first embodiment of the present technology.

FIG. 8 is a circuit diagram depicting a configuration example of the reference voltage generating circuit using the ground voltage as a reference and the low-voltage-side voltage regulator according to the first embodiment of the present technology.

FIG. 9 is a circuit diagram depicting a configuration example of the reference voltage generating circuit using the power supply voltage as a reference and the low-voltage-side voltage regulator according to the first embodiment of the present technology.

FIG. 10 is a diagram depicting an example of the waveform of an output signal in the first embodiment of the present technology and in a comparative example.

FIG. 11 is a block diagram depicting a configuration example of a driving circuit according to a second embodiment of the present technology.

FIG. 12 is a circuit diagram depicting a configuration example of the reference voltage generating circuit using a ground voltage as a reference and the high-voltage-side voltage regulator according to the second embodiment of the present technology.

FIG. 13 is a circuit diagram depicting a configuration example of the reference voltage generating circuit using a power supply voltage as a reference and the high-voltage-side voltage regulator according to the second embodiment of the present technology.

FIG. 14 is a circuit diagram depicting a configuration example of the reference voltage generating circuit using the ground voltage as a reference and a high-voltage-side voltage regulator with a different feedback circuit according to the second embodiment of the present technology.

FIG. 15 is a circuit diagram depicting a configuration example of the reference voltage generating circuit using the power supply voltage as a reference and the high-voltage-side voltage regulator with the different feedback circuit according to the second embodiment of the present technology.

FIG. 16 is a circuit diagram depicting a configuration example of the low-voltage-side voltage regulator according to the second embodiment of the present technology.

FIG. 17 is a circuit diagram depicting a configuration example of the low-voltage-side voltage regulator with a different feedback circuit according to the second embodiment of the present technology.

FIG. 18 is a block diagram depicting an example of schematic configuration of a vehicle control system.

FIG. 19 is a diagram of assistance in explaining an example of installation positions of an outside-vehicle information detecting section and an imaging section.

### DESCRIPTION OF EMBODIMENTS

Modes for implementing the present technology (hereinafter referred to as embodiments) will be described below. The description will be given in the following order.

1. First Embodiment (example in which a high-voltage-side voltage regulator generates a high voltage from a low voltage)

2. Second Embodiment (example in which a low-voltage-side voltage regulator generates a low voltage from a high voltage)

3. Example of Application to Mobile Body

### 1. First Embodiment

### [Configuration Example of Interface Circuit]

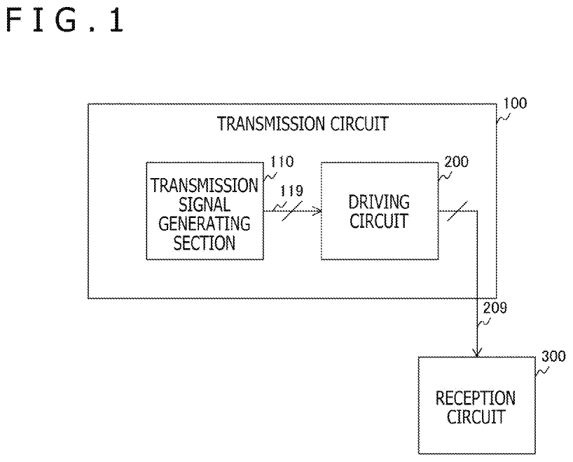

FIG. 1 is a block diagram depicting a configuration example of an interface circuit according to an embodiment of the present technology. The interface circuit is a circuit for transmitting signals, and includes a transmission circuit 100 and a reception circuit 300.

The transmission circuit 100 is a circuit that transmits signals, and includes a transmission signal generating section 110 and a driving circuit 200.

The transmission signal generating section 110 generates signals to be transmitted. The transmission signal generating section 110, for example, generates and supplies a differential signal to the driving circuit 200 via a signal line 119.

The driving circuit 200 amplifies the differential signal supplied from the transmission signal generating section 110 and outputs the amplified differential signal to the transmission line 209. The reception circuit 300 uses a receiver or the like to receive the differential signal from the driving circuit 200.

### [Configuration Example of Driving Circuit]

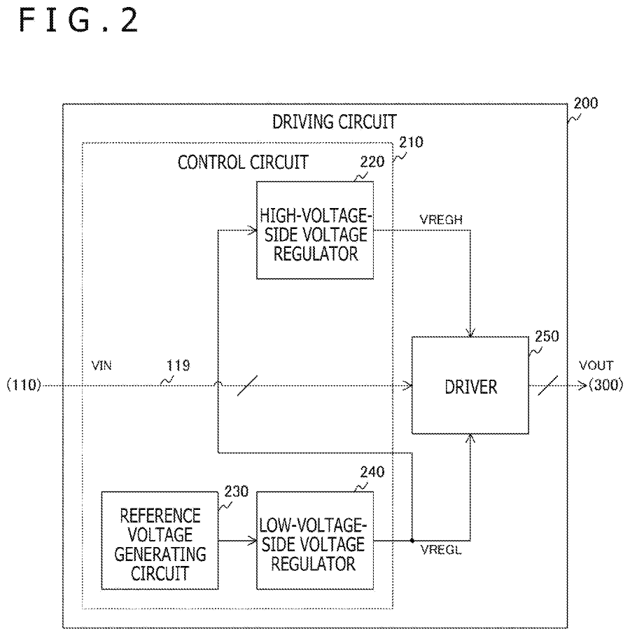

FIG. 2 is a block diagram depicting a configuration example of the driving circuit 200 according to the first embodiment of the present technology. The driving circuit 200 includes a control circuit 210 and a driver 250.

The control circuit 210 controls the amplitude of an output signal from the driver 250. The control circuit 210 includes a high-voltage-side voltage regulator 220, a reference voltage generating circuit 230, and a low-voltage-side voltage regulator 240.

The driver 250 adjusts the amplitude of a differential signal VIN supplied from the transmission signal generating section 110 and outputs a resultant differential signal VOUT to the reception circuit 300. A high voltage VREGH is input to a power supply terminal of the driver 250. In addition, a low voltage VREGL lower than the high voltage VREGH is input to a ground terminal of the driver 250. Note that the high voltage VREGH and the low voltage VREGL are an example of a pair of voltages described in the claims.

The reference voltage generating circuit 230 generates and supplies a predetermined reference voltage to the low-voltage-side voltage regulator 240.

The low-voltage-side voltage regulator 240 generates a low voltage VREGL from the reference voltage and supplies the low voltage VREGL to the ground terminal of the driver 250 and the high-voltage-side voltage regulator 220. Note that the low-voltage-side voltage regulator 240 is an example of a first voltage regulator described in the claims.

The high-voltage-side voltage regulator 220 uses the low voltage VREGL as a reference voltage to generate a high voltage VREGH from the reference voltage and supplies the high voltage VREGH to the power supply terminal of the driver 250. Note that the high-voltage-side voltage regulator 220 is an example of a second voltage regulator described in the claims.

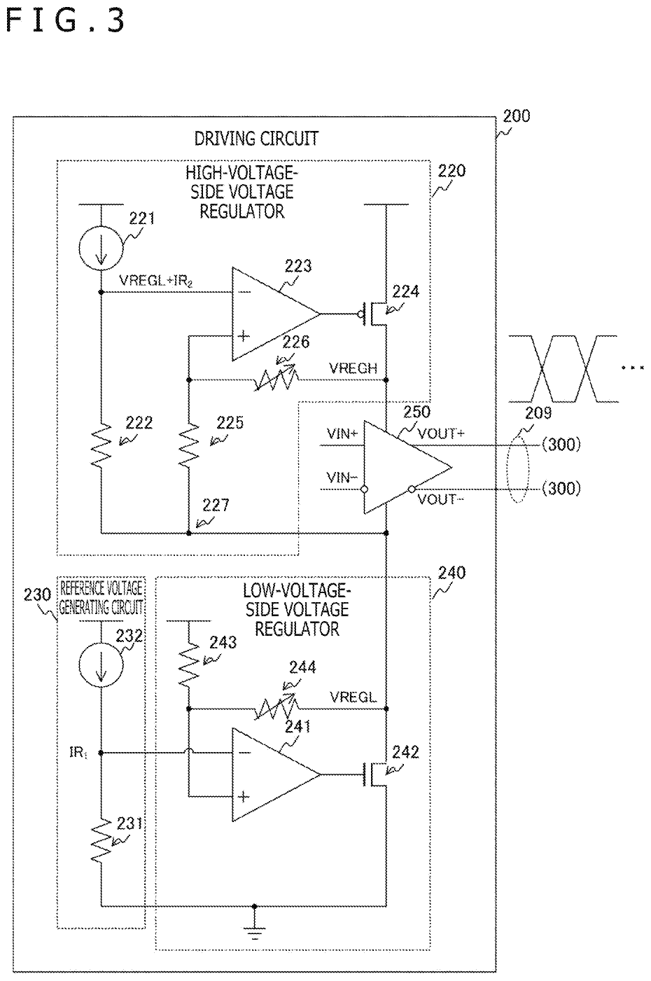

FIG. 3 is a circuit diagram depicting a configuration example of the driving circuit 200 according to the first embodiment of the present technology. The high-voltage-side voltage regulator 220 includes a current source 221, a resistor 222, an operational amplifier 223, a pMOS (p-channel Metal Oxide Semiconductor) transistor 224, a resistor 225, and a variable resistor 226.

The current source 221 and the resistor 222 are interposed in series between the power supply voltage and a node 227. The node 227 is connected to the low-voltage-side voltage regulator 240 and receives, as input, the low voltage VREGL from the low-voltage-side voltage regulator 240.

An inverting input terminal (−) of the operational amplifier 223 is connected to a connection node between the current source 221 and the resistor 222. A voltage corresponding to the low voltage VREGL is input to the inverting input terminal (−).

The pMOS transistor 224 is interposed between the power supply voltage and the power supply terminal of the driver 250. A gate of the pMOS transistor 224 is connected to an output terminal of the operational amplifier 223.

The resistor 225 is connected at one end to a non-inverting input terminal (+) of the operational amplifier 223 and at the other end to the node 227. The variable resistor 226 is interposed between the non-inverting input terminal (+) of the operational amplifier 223 and the power supply terminal of the driver 250. Note that the operational amplifier 223 is an example of a second operational amplifier described in the claims. In addition, the variable resistor 226 is an example of a third resistor described in the claims, and the resistor 225 is an example of a fourth resistor described in the claims.

The reference voltage generating circuit 230 includes a current source 232 and a resistor 231. The current source 232 and the resistor 231 are connected in series between the power supply voltage and the ground voltage.

In addition, the low-voltage-side voltage regulator 240 includes an operational amplifier 241, an nMOS (n-channel MOS) transistor 242, a resistor 243, and a variable resistor 244.

An inverting input terminal (−) of the operational amplifier 241 is connected to the connection node between the current source 232 and the resistor 231. The voltage of the node is input to the inverting input terminal (−) as a reference voltage.

The nMOS transistor 242 is interposed between the ground terminal of the driver 250 and the ground voltage. A gate of the nMOS transistor 242 is connected to an output terminal of the operational amplifier 241.

The power supply voltage is applied to one end of the resistor 243, and the other end of the resistor 243 is connected to the non-inverting input terminal (+) of the operational amplifier 241. The variable resistor 244 is interposed between the non-inverting input terminal (+) of the operational amplifier 241 and the ground terminal of the driver 250. Note that the operational amplifier 241 is an example of a first operational amplifier described in the claims. In addition, the variable resistor 244 is an example of a first resistor described in the claims, and the resistor 243 is an example of a second resistor described in the claims.

In addition, the differential signal VOUT includes a positive-phase signal VOUT+ and a negative-phase signal VOUT− that have different phases. The driver 250 outputs one of the high voltage VREGH and the low voltage VREGL as the positive-phase signal VOUT+. When the positive-phase signal VOUT+ is at the high voltage VREGH, the negative-phase signal VOUT− is set to the low voltage VREGL. When the positive-phase signal VOUT+ is at the low voltage VREGL, the negative-phase signal VOUT− is set to the high voltage VREGH.

Note that differential signals are input to and output from the driver 250 but that single-end signals can be input to and output from the driver 250.

In the circuit configuration illustrated in FIG. 3, the reference voltage generating circuit 230 generates a reference voltage by using the ground voltage as a reference. For example, when the resistor 231 is assumed to have a resistance value R₁ and the current source 232 is assumed to have a current value I, a voltage that is higher than the ground voltage by I×R₁ is generated as a reference voltage.

In addition, the low-voltage-side voltage regulator 240 amplifies the reference voltage by using a gain G₁, and outputs the amplified voltage as the low voltage VREGL. Here, the gain G₁ is expressed by the following equation.

G₁=R₄/R₃ Equation 1

In the above equation, R₄ is the resistance value of the variable resistor 244. R₃ is the resistance value of the resistor 243.

The gain G₂ can be adjusted by changing the resistance value of the variable resistor 244 according to Equation 1.

Here, the operational amplifier 241 may be subjected to input offset ofs₁ due to variation among elements in the operational amplifier 223. In view of the input offset ofs₁, the low voltage VREGL is expressed by the following equation.

VREGL=(IR₁+ofs₁)×G₁ Equation 2

In the above equation, the terms of the low voltage VREGL, IR₁, and the input offset ofs₁ are in units of, for example, millivolts (mV).

In addition, the high-voltage-side voltage regulator 220 amplifies a voltage corresponding to the low voltage VREGL by using a gain G₂, and outputs the amplified voltage as the low voltage VREGL. Here, the gain G₂ is expressed by the following equation.

G₂=R₆/R₅ Equation 3

In the above equation, R₆ is the resistance value of the variable resistor 266. R₅ is the resistance value of the resistor 225.

The gain G₂ can be adjusted by changing the resistance value of the variable resistor 226 according to Equation 3.

In view of an input offset ofs₂ of the operational amplifier 223, the high voltage VREGH is expressed by the following equation.

VREGH=(VREGL+IR₁+ofs₂)×G₂ Equation 4

In the above equation, the terms of the high voltage VREGH and the input offset ofs₂ are in units of, for example, millivolts (mV).

In addition, an amplitude A of an output from the driver 250 is expressed by the following equation.

A=VREGH−VREGL Equation 5

By substituting Equations 2 and 4 into Equation 5, and transforming the resultant equation, the following equations are obtained.

A=VREG+ΔVREG Equation 6

VREG=G₁(1−G₂)×IR₁+G₂×IR₂ Equation 7

ΔVREG=G₁(1−G₂)×ofs₁+G₂×ofs₂ Equation 8

VREG in Equation 6 is the amplitude obtained in a case where no input offset occurs, and ΔVREG is variation in amplitude caused by input offset. The ratio between VREG and ΔVREG is expressed by the following equation on the basis of Equations 7 and 8.

ΔVREG/VREG={G₁(1−G₂)×ofs₁+G₂×ofs₂}/{G₁(1−G₂)×IR₁+G₂×IR₂} Equation 9

Here, when the gain G₂is assumed to be “1,” the following equation is obtained from Equation 9.

ΔVREG/VREG=ofs₂/IR₂ Equation 10

For example, when VREG is assumed to be 450 millivolts (mV) and the input offset ofs₂ is assumed to be 5 millivolts (mV), the amplitude varies approximately 1.1% on the basis of Equation 10. Note that, in a case where a gain G₂ is other than “1,” the term of the input offset ofs₁ remains but that, even in this case, the input offset ofs₁ has a low impact compared to the input offset ofs₂.

Equation 10 indicates that, by using a configuration in which the high-voltage-side voltage regulator 220 references the low voltage VREGL and generates the high voltage VREGH from the low voltage VREGL, variation in amplitude that is caused by the offset ofs₁ of the operational amplifier 241 can be reduced. Thus, accuracy achieved when the control circuit 210 controls the amplitude can be improved.

Here, as a comparative example, assumed is a configuration in which the high-voltage-side voltage regulator 220 and the low-voltage-side voltage regulator 240 use an identical reference voltage.

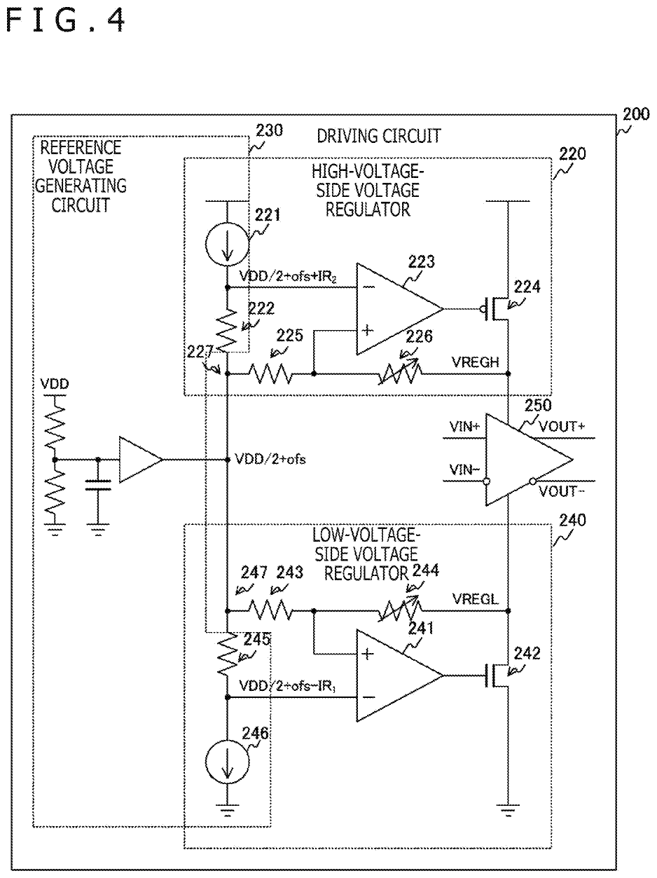

FIG. 4 is a circuit diagram depicting a configuration example of the driving circuit 200 according to a comparative example. In the high-voltage-side voltage regulator 220 in the comparative example, the input-side node 227 is not connected to the low-voltage-side voltage regulator 240 but is connected to the reference voltage generating circuit.

In addition, in the comparative example, the low-voltage-side voltage regulator 240 is further provided with a resistor 245 and a current source 246. The resistor 245 and the current source 246 are connected in series between a node 247 to which the reference voltage is supplied and the ground voltage. In addition, one end of the resistor 243 is connected to the node 247 instead of to the power supply voltage.

In the comparative example, the reference voltage generating circuit 230 uses a resistive divider circuit or an operational amplifier to supply a reference voltage VREF expressed by the following equation.

VREF=VDD/2+ofs Equation 11

In the above equation, VDD is the power supply voltage, and ofs is the input offset of the operational amplifier in the reference voltage generating circuit. When the resistor 245 has a resistance value of R₁ similarly to the resistor 231, the low voltage VREGL is expressed by the following equation on the basis of Equation 11.

VREGL=VDD/2+ofs−(IR₁+ofs₁)×G₁ Equation 12

In addition, the high voltage VREGH is expressed by the following equation on the basis of Equation 11.

VREGH=VDD/2+ofs+(IR₁+ofs₂)×G₂ Equation 13

Equations 12 and 13 provide the following equation.

ΔVREG/VREG=(G₁×ofs₁+G₂×ofs₂)/(G₁×IR₁+G₂×IR₂) Equation 14

When the gains G₁ and G₂ are each assumed to be “1,” VREG is assumed to be 450 millivolts (mV), and the input offsets ofs₁ and ofs₂ are each assumed to be 5 millivolts (mV), the amplitude varies approximately 2.2% on the basis of Equation 14.

As illustrated in Equations 9 and 14, in a case where the high-voltage-side voltage regulator 220 references the low voltage VREGL, the impact of ofs₁ can be canceled. In contrast, in the comparative example in which the high-voltage-side voltage regulator 220 does not reference the low voltage VREGL, the impact of ofs₁ fails to be canceled. Consequently, the latter involves a larger variation in amplitude caused by the offset voltage.

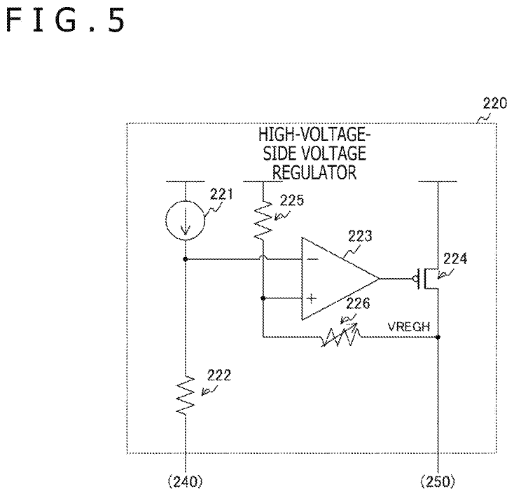

FIG. 5 is a circuit diagram depicting a configuration example of the high-voltage-side voltage regulator 220 with a different feedback circuit according to the first embodiment of the present technology. As illustrated in FIG. 5, the power supply voltage can be applied to the other end of the resistor 225. This connection allows the feedback circuit on the high voltage side to be changed compared to the configuration in FIG. 3.

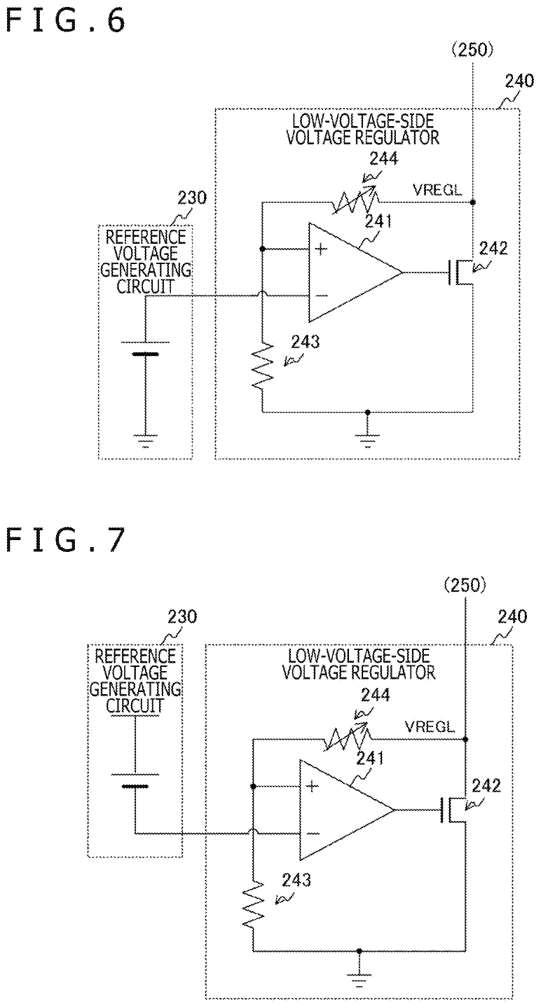

FIG. 6 is a circuit diagram depicting a configuration example of the reference voltage generating circuit 230 using the ground voltage as a reference and the low-voltage-side voltage regulator 240 with a different feedback circuit according to the first embodiment of the present technology.

FIG. 7 is a circuit diagram depicting a configuration example of the reference voltage generating circuit 230 using the power supply voltage as a reference and the low-voltage-side voltage regulator 240 with the different feedback circuit according to the first embodiment of the present technology.

As illustrated in FIGS. 6 and 7, the ground voltage can be applied to the other end of the resistor 243. This connection allows the feedback circuit on the low voltage side to be changed compared to the configuration in FIG. 3.

In addition, the reference voltage generating circuit 230 can generate a reference voltage by using the ground voltage as a reference as illustrated in FIG. 6 or by using the power supply voltage as a reference as illustrated in FIG. 7. In a case where the ground voltage is used as a reference, a voltage that is higher than the ground voltage by a predetermined voltage is supplied as the reference voltage, for example. In a case where the power supply voltage is used as a reference, a voltage that is lower than the power supply voltage by a predetermined voltage is supplied as the reference voltage, for example.

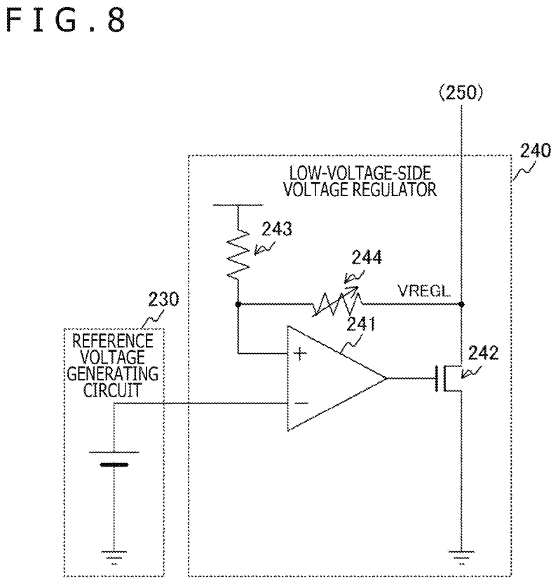

FIG. 8 is a circuit diagram depicting a configuration example of the reference voltage generating circuit 230 using the ground voltage as a reference and the low-voltage-side voltage regulator 240 according to the first embodiment of the present technology.

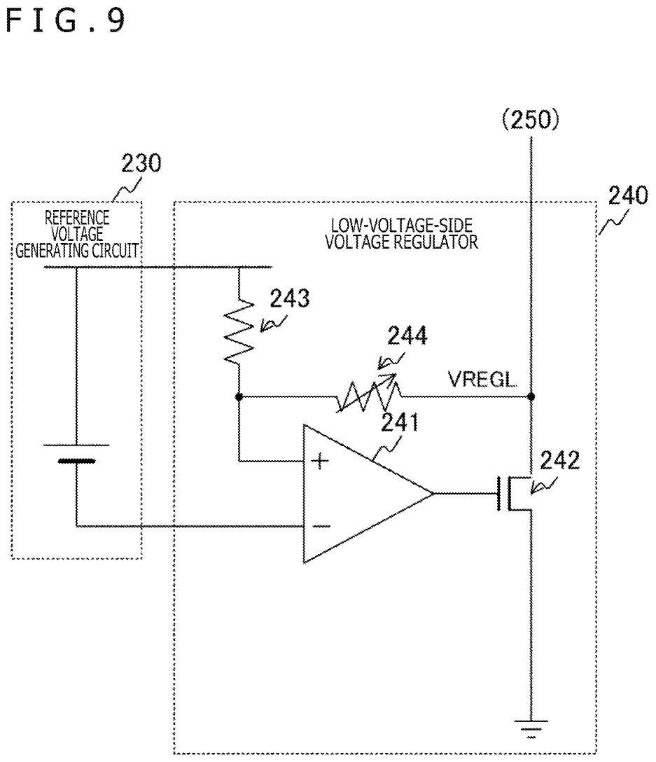

FIG. 9 is a circuit diagram depicting a configuration example of the reference voltage generating circuit 230 using the power supply voltage as a reference and the low-voltage-side voltage regulator 240 according to the first embodiment of the present technology.

The circuits of the low-voltage-side voltage regulators 240 in FIGS. 8 and 9 are similar to that depicted in FIG. 3. The reference voltage generating circuit 230 connected to the low-voltage-side voltage regulator 240 can use the ground voltage as a reference as illustrated in FIG. 8 or use the power supply voltage as a reference as illustrated in FIG. 9.

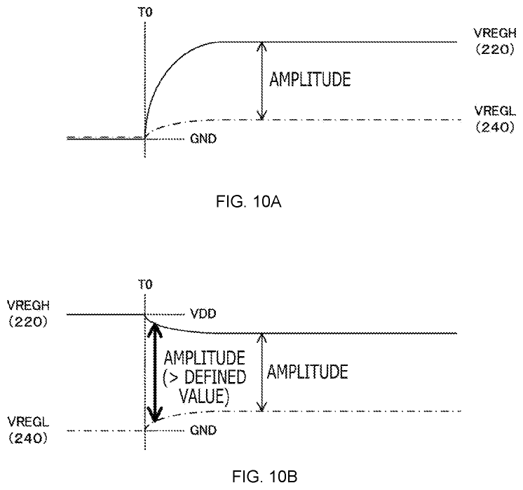

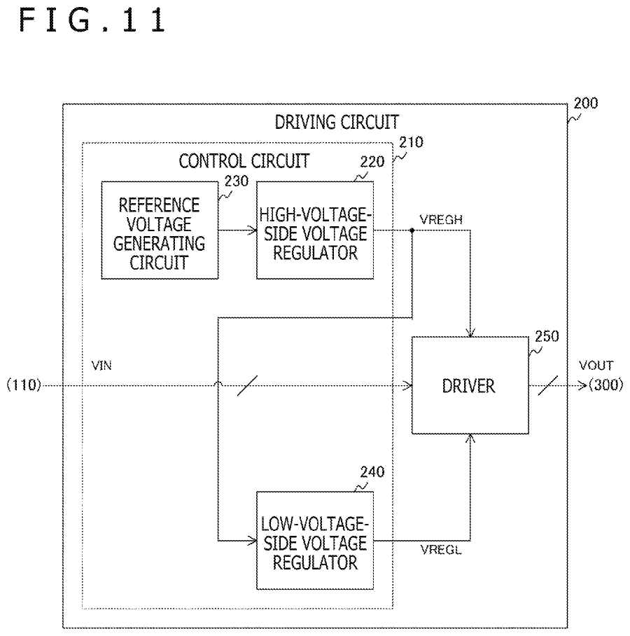

FIG. 10 is a diagram depicting an example of the waveform of an output signal in the first embodiment of the present technology and in the comparative example. In FIG. 10, “a” is a diagram depicting an example of the waveform of an output signal from the driver 250 in the first embodiment of the present technology. In FIG. 10, “b” is a diagram depicting an example of the waveform of an output signal from the driver 250 in the comparative example in which the high-voltage-side voltage regulator 220 does not reference the low voltage VREGL. In FIG. 10, solid lines indicate the waveform of the high voltage VREGH, and alternate long and short dash lines indicate the waveform of the low voltage VREGL.

As illustrated in “a” of FIG. 10, in a case where the high-voltage-side voltage regulator 220 references the low voltage VREGL, when the control circuit 210 starts control at timing TO, the high voltage VREGH and the low voltage VREGL gradually rise. Then, the difference between the high voltage VREGH and the low voltage VREGL (that is, the amplitude) has a constant value.

In addition, as illustrated in “b” of FIG. 10, in the comparative example in which the high-voltage-side voltage regulator 220 does not reference the low voltage VREGL, when the control circuit 210 starts control at timing TO, the high voltage VREGH gradually lowers. On the other hand, the low voltage VREGL gradually rises. Then, the difference between the high voltage VREGH and the low voltage VREGL (that is, the amplitude) has a constant value. As illustrated in “b” of FIG. 10, in the comparative example, a signal with an amplitude larger than a defined value may accidentally be transmitted to the reception side. On the other hand, as illustrated in “a” of FIG. 10, no signal with an amplitude larger than the defined value is transmitted in the configuration in which the high-voltage-side voltage regulator 220 references the low voltage VREGL.

Thus, according to the first embodiment of the present technology, the high-voltage-side voltage regulator 220 generates the high voltage VREGH from the low voltage VREGL, allowing suppression of the input offset ofs₁, which occurs on the low voltage side. This enables reduction in variation in amplitude caused by the input offset ofs₁, allowing improvement of accuracy achieved when the control circuit 210 controls the amplitude.

### 2. Second Embodiment

In the first embodiment described above, the high-voltage-side voltage regulator 220 references the low voltage VREGL. However, in this configuration, in a case where the input offset ofs₂ on the high voltage side is relatively large, the accuracy of the control of the amplitude may be reduced. The driving circuit 200 of the second embodiment differs from the driving circuit 200 of the first embodiment in that the low-voltage-side voltage regulator 240 references the high voltage VREGH.

FIG. 11 is a block diagram depicting a configuration example of the driving circuit 200 according to the second embodiment of the present technology. In the driving circuit 200 of the second embodiment, the reference voltage generating circuit 230 supplies the reference voltage to the high-voltage-side voltage regulator 220. The high-voltage-side voltage regulator 220 generates the high voltage VREGH from the reference voltage, and supplies the high voltage VREGH to the power supply terminal of the driver 250 and to the low-voltage-side voltage regulator 240. In addition, the low-voltage-side voltage regulator 240 uses the high voltage VREGH as a reference voltage to generate the low voltage VREGL from the reference voltage, and supplies the low voltage VREGL to the ground terminal of the driver 250.

Instead of Equation 10, the configuration in FIG. 11 provides the following equation.

ΔVREG/VREG=ofs₁/IR₁ Equation 15

Note that the high-voltage-side voltage regulator 220 is an example of the first voltage regulator described in the claims. In addition, the low-voltage-side voltage regulator 240 is an example of the second voltage regulator described in the claims.

As illustrated in FIG. 2 and FIG. 11, the high-voltage-side voltage regulator 220 can reference the low voltage VREGL, and the low-voltage-side voltage regulator 240 can reference the high voltage VREGH.

Equations 10 and 15 indicate that the configuration in FIG. 2 is desirably used in a case where the input offset ofs₁ on the low voltage side is relatively large. On the other hand, the configuration in FIG. 11 is desirably used in a case where the input offset ofs₂ on the high voltage side is relatively large.

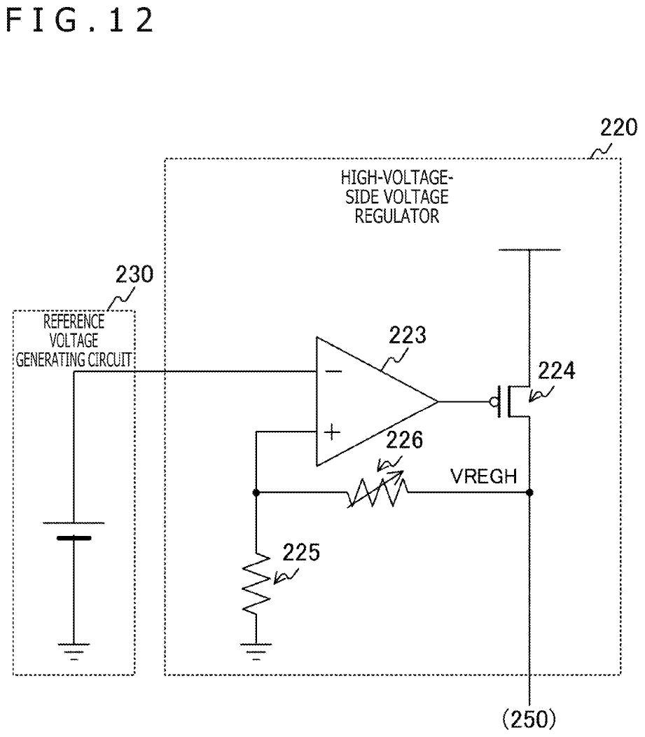

FIG. 12 is a circuit diagram depicting a configuration example of the reference voltage generating circuit 230 using the ground voltage as a reference and the high-voltage-side voltage regulator 220 according to the second embodiment of the present technology. The high-voltage-side voltage regulator 220 of the second embodiment differs from the high-voltage-side voltage regulator 220 in the first embodiment in that the current source 221 and the resistor 222 are not disposed in the high-voltage-side voltage regulator 220 of the second embodiment. In addition, the inverting input terminal (−) of the operational amplifier 223 receives, as input, the reference voltage from the reference voltage generating circuit 230. The non-inverting input terminal (+) of the operational amplifier 223 is connected to the connection node between the resistor 225 and the variable resistor 226. The resistor 225 is connected at one end to the non-inverting input terminal (+), and the ground voltage is applied to the other end of the resistor 225.

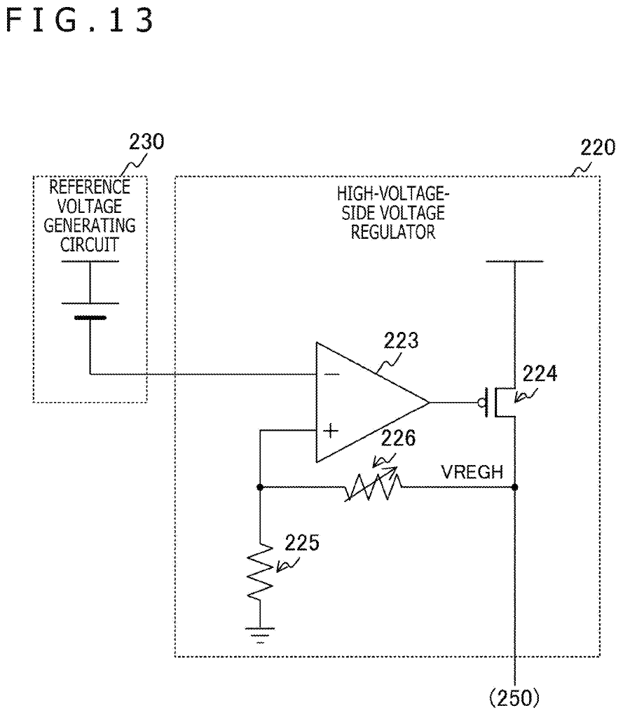

FIG. 13 is a circuit diagram depicting a configuration example of the reference voltage generating circuit 230 using the power supply voltage as a reference and the high-voltage-side voltage regulator 220 according to the second embodiment of the present technology.

The reference voltage generating circuit 230 can generate a reference voltage by using the ground voltage as a reference as illustrated in FIG. 12 or by using the power supply voltage as a reference as illustrated in FIG. 13.

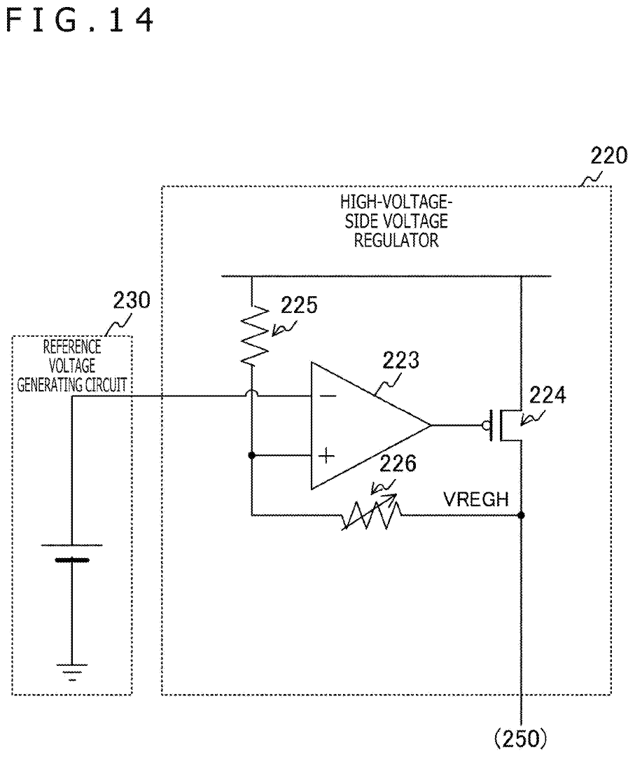

FIG. 14 is a circuit diagram depicting a configuration example of a reference voltage generating circuit using the ground voltage as a reference and the high-voltage-side voltage regulator with a different feedback circuit according to the second embodiment of the present technology.

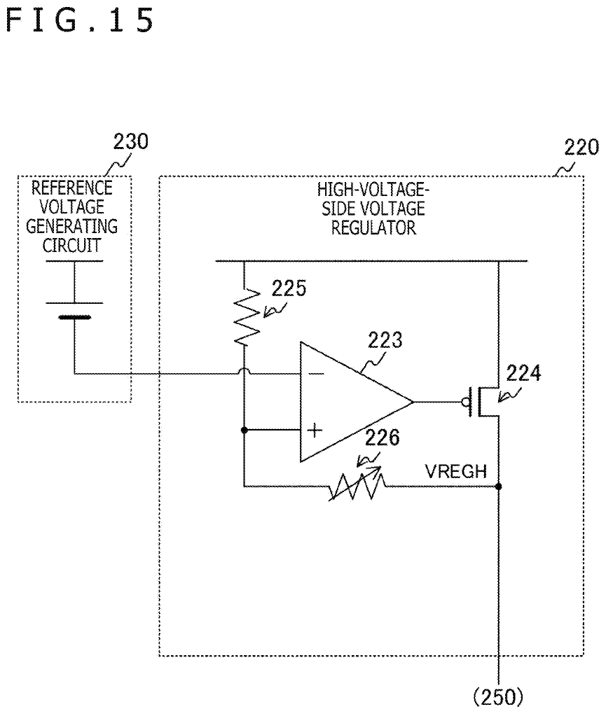

FIG. 15 is a circuit diagram depicting a configuration example of the reference voltage generating circuit using the power supply voltage as a reference and the high-voltage-side voltage regulator with the different feedback circuit according to the second embodiment of the present technology.

As illustrated in FIGS. 14 and 15, the power supply voltage can also be applied to the other end of the resistor 225. This connection allows the feedback circuit of the operational amplifier 223 to be changed compared to the configurations in FIGS. 12 and 13.

In addition, the reference voltage generating circuit 230 can generate a reference voltage by using the ground voltage as a reference as illustrated in FIG. 14 or by using the power supply voltage as a reference as illustrated in FIG. 15.

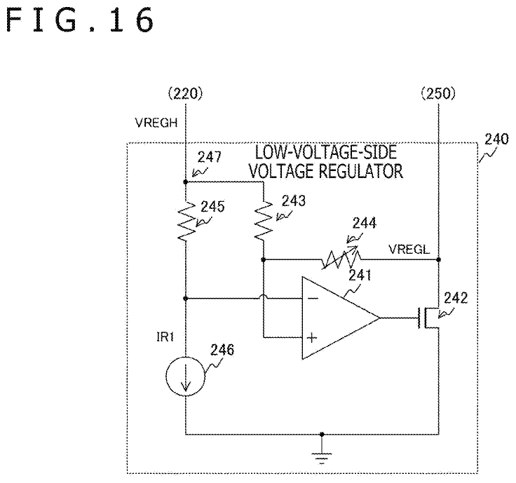

FIG. 16 is a circuit diagram illustrating a configuration example of the low-voltage-side voltage regulator 240 according to the second embodiment of the present technology. The low-voltage-side voltage regulator 240 of the second embodiment differs from the low-voltage-side voltage regulator 240 of the first embodiment in that the resistor 245 and the current source 246 are further disposed in the low-voltage-side voltage regulator 240 of the second embodiment.

The resistor 245 and the current source 246 are connected in series between the node 247 to which the high voltage VREGH is input and the ground voltage. In addition, the inverting input terminal (−) of the operational amplifier 241 is connected to the connection node between the resistor 245 and the current source 246. The non-inverting input terminal (+) of the operational amplifier 241 is connected to the connection node between the resistor 243 and the variable resistor 244. The resistor 243 is connected at one end to the non-inverting input terminal (+) and at the other end to the node 247.

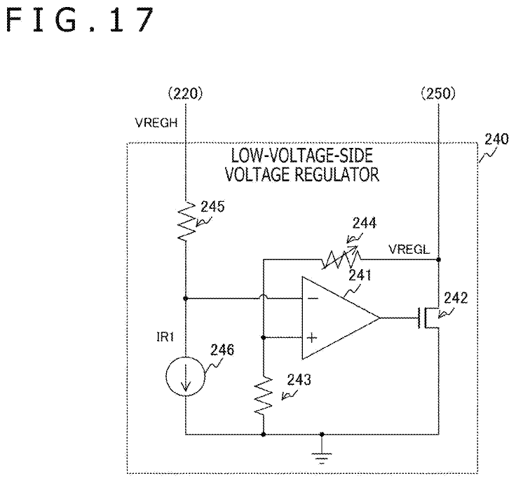

FIG. 17 is a circuit diagram of a configuration example of the low-voltage-side voltage regulator 240 with a different feedback circuit according to the second embodiment of the present technology. As illustrated in FIG. 17, the ground voltage can be applied to the other end of the resistor 243.

As described above, according to the second embodiment of the present technology, the low-voltage-side voltage regulator 240 generates the low voltage VREGL from the high voltage VREGH, allowing suppression of the input offset ofs₂, which occurs on the high voltage side. This enables reduction in variation in amplitude caused by the input offset ofs₂, allowing improvement of accuracy achieved when the control circuit 210 controls the amplitude.

### <3. Example of Application to Mobile Body>

The technology according to the present disclosure (present technology) can be applied to various products. For example, the technology according to the present technology may be implemented as an apparatus mounted in any type of mobile bodies such as an automobile, an electric automobile, a hybrid electric automobile, a motor cycle, a bicycle, a personal transporter, an airplane, a drone, a ship, or a robot.

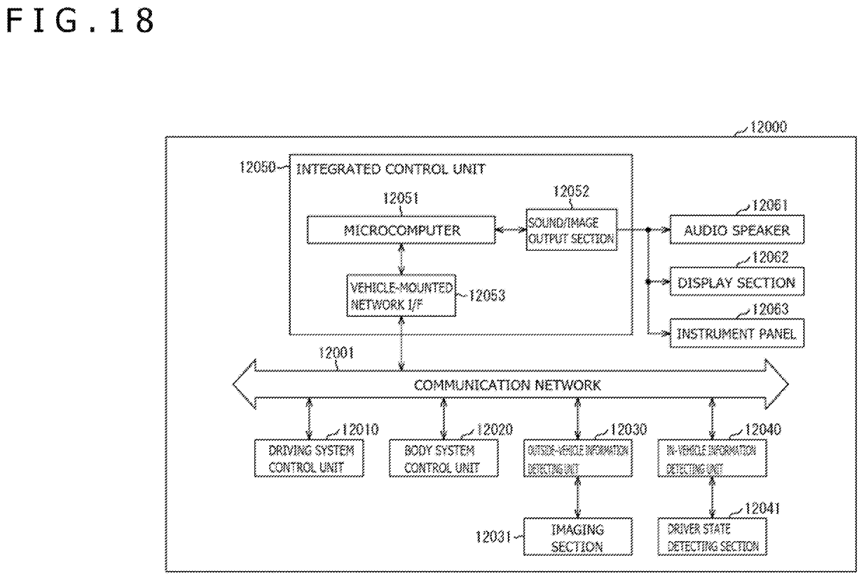

FIG. 18 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 18, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 18, an audio speaker 12061, a display section 12062, and an instrument panel 12063 are illustrated as the output device. The display section 12062 may, for example, include at least one of an on-board display and a head-up display.

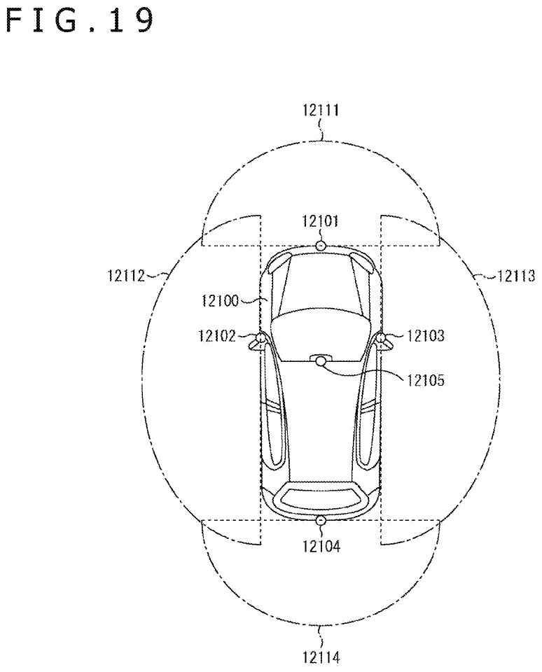

FIG. 19 is a diagram depicting an example of the installation position of the imaging section 12031.

In FIG. 19, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 19 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described. The technology according to the present disclosure can be applied to the imaging section 12031 of the configuration described above. Specifically, the transmission circuit 100 in FIG. 1 can be applied to the communication interface of the imaging section 12031. By application of the technology according to the present disclosure to the imaging section 12031, the control accuracy for the amplitude is improved, allowing signal quality to be improved.

Note that the above-described embodiments are illustrated as examples for embodying the present technology, and the elements of the embodiments respectively have correspondence relations with specific elements of the invention described in the claims. Similarly, the specific elements of the invention described in the claims respectively have correspondence relations with the elements of the embodiments of the present technology having the same names as those of the specific elements. However, the present technology is not limited to the embodiments and can be embodied by making various modifications to the embodiments without departing from the spirits of the present technology.

Note that the effects described herein are only illustrative and not restrictive and that the present technology may produce any other effects.

Note that the present technology can also be configured as follows.

(1)

A control circuit including:

a first voltage regulator that generates one of a pair of voltages from a predetermined reference voltage and supplies the one of the pair of voltages to one of a power supply terminal and a ground terminal of a driver; and

a second voltage regulator that generates the other of the pair of voltages from the one of the pair of voltages and supplies the other of the pair of voltages to the other of the power supply terminal and the ground terminal.

(2)

The control circuit according to (1) described above, in which

the first voltage regulator generates a lower voltage of the pair of voltages, and

the second voltage regulator generates a higher voltage of the pair of voltages.

(3)

The control circuit according to (1) described above, in which

the first voltage regulator generates a higher voltage of the pair of voltages, and

the second voltage regulator generates a lower voltage of the pair of voltages.

(4)

The control circuit according to any one of (1) to (3) described above, further including:

a reference voltage generating circuit that generates and supplies the reference voltage to the first voltage regulator.

(5)

The control circuit according to (4) described above, in which

the reference voltage generating circuit generates the reference voltage by using a predetermined ground voltage as a reference.

(6)

The control circuit according to (4) described above, in which

the reference voltage generating circuit generates the reference voltage by using a predetermined power supply voltage as a reference.

(7)

The control circuit according to any one of (1) to (6) described above, in which

the first voltage regulator includes
a first operational amplifier that outputs the one of the pair of voltages,
a first resistor interposed between one of a pair of input terminals of the first operational amplifier and the one of the power supply terminal and the ground terminal, and
a second resistor connected at one end to the one of the pair of input terminals, and

the other of the pair of input terminals receives the reference voltage as input.

(8)

The control circuit according to (7) described above, in which

a predetermined ground voltage is applied to the other end of the second resistor.

(9)

The control circuit according to (7) described above, in which

a predetermined power supply voltage is applied to the other end of the second resistor.

(10)

The control circuit according to (7) described above, in which

the second voltage regulator includes
a second operational amplifier that outputs the other of the pair of voltages,
a third resistor interposed between one of a pair of input terminals of the second operational amplifier and the other of the power supply terminal and the ground terminal, and
a fourth resistor connected at one end to the one of the pair of input terminals, and

a voltage corresponding to the one of the pair of voltages is applied to the other of the pair of input terminals.

(11)

The control circuit according to (10) described above, in which

the one of the pair of voltages is applied to the other end of the fourth resistor.

(12)

The control circuit according to (10) described above, in which

a predetermined power supply voltage is applied to the other end of the fourth resistor.

(13)

A driving circuit including:

a driver;

a first voltage regulator that generates one of a pair of voltages from a predetermined reference voltage and supplies the one of the pair of voltages to one of a power supply terminal and a ground terminal of the driver; and

a second voltage regulator that generates the other of the pair of voltages from the one of the pair of voltages and supplies the other of the pair of voltages to the other of the power supply terminal and the ground terminal.

### REFERENCE SIGNS LIST

100: Transmission circuit

110: Transmission signal generating section

200: Driving circuit

210: Control circuit

220: High-voltage-side voltage regulator

221, 232, 246: Current source

222, 225, 231, 243, 245: Resistor

223, 224: Operational amplifier

224: pMOS transistor

226, 244: Variable resistor

230: Reference voltage generating circuit

240: Low-voltage-side voltage regulator

242: nMOS transistor

250: Driver

300: Reception circuit

12031: Imaging section

1. A control circuit comprising:
a first voltage regulator that generates one of a pair of voltages from a predetermined reference voltage and supplies the one of the pair of voltages to one of a power supply terminal and a ground terminal of a driver; and
a second voltage regulator that generates the other of the pair of voltages from the one of the pair of voltages and supplies the other of the pair of voltages to the other of the power supply terminal and the ground terminal.

2. The control circuit according to claim 1, wherein
the first voltage regulator generates a lower voltage of the pair of voltages, and
the second voltage regulator generates a higher voltage of the pair of voltages.

3. The control circuit according to claim 1, wherein
the first voltage regulator generates a higher voltage of the pair of voltages, and
the second voltage regulator generates a lower voltage of the pair of voltages.

4. The control circuit according to claim 1, further comprising:
a reference voltage generating circuit that generates and supplies the reference voltage to the first voltage regulator.

5. The control circuit according to claim 4, wherein
the reference voltage generating circuit generates the reference voltage by using a predetermined ground voltage as a reference.

6. The control circuit according to claim 4, wherein
the reference voltage generating circuit generates the reference voltage by using a predetermined power supply voltage as a reference.

7. The control circuit according to claim 1, wherein
the first voltage regulator includes
a first operational amplifier that outputs the one of the pair of voltages,
a first resistor interposed between one of a pair of input terminals of the first operational amplifier and the one of the power supply terminal and the ground terminal, and
a second resistor connected at one end to the one of the pair of input terminals, and
the other of the pair of input terminals receives the reference voltage as input.

8. The control circuit according to claim 7, wherein
a predetermined ground voltage is applied to the other end of the second resistor.

9. The control circuit according to claim 7, wherein
a predetermined power supply voltage is applied to the other end of the second resistor.

10. The control circuit according to claim 7, wherein
the second voltage regulator includes
a second operational amplifier that outputs the other of the pair of voltages,
a third resistor interposed between one of a pair of input terminals of the second operational amplifier and the other of the power supply terminal and the ground terminal, and
a fourth resistor connected at one end to the one of the pair of input terminals, and
a voltage corresponding to the one of the pair of voltages is applied to the other of the pair of input terminals.

11. The control circuit according to claim 10, wherein
the one of the pair of voltages is applied to the other end of the fourth resistor.

12. The control circuit according to claim 10, wherein
a predetermined power supply voltage is applied to the other end of the fourth resistor.

13. A driving circuit comprising:
a driver;
a first voltage regulator that generates one of a pair of voltages from a predetermined reference voltage and supplies the one of the pair of voltages to one of a power supply terminal and a ground terminal of the driver; and
a second voltage regulator that generates the other of the pair of voltages from the one of the pair of voltages and supplies the other of the pair of voltages to the other of the power supply terminal and the ground terminal.
